(19) United States
(12) Patent Application Publication
(10) Pub. No.: US 2020/0312635 A1
(43) Pub. Date: Oct. 1, 2020

(54) PLASMA FOCUS RING OF SEMICONDUCTOR ETCHING APPARATUS AND MANUFACTURING METHOD THEREOF

(71) Applicant: ONE SEMICON. CO., LTD., Incheon (KR)

(72) Inventors: Ki Sang KIM, Seoul (KR); Weon Gyu LEE, Incheon (KR); Jae Hong JUN, Yongin-si (KR)

(21) Appl. No.: 16/835,104

(22) Filed: Mar. 30, 2020

(30) Foreign Application Priority Data
Apr. 1, 2019 (KR) 10-2019-0038097

(51) Int. Cl. H01J 37/32; H01L 21/67; H01L 21/683

(52) U.S. Cl. CPC H01J 37/32642; H01J 37/32715; H01L 21/6831; H01L 21/67069

(57) ABSTRACT

The present invention relates to a plasma focus ring of a semiconductor etching apparatus and a manufacturing method thereof, which can improve processability, extend lifespan, and reduce replacement cost by manufacturing a plurality of divided components of the plasma focus ring and combining the components, and the plasma focus ring comprises: an upper plasma focus ring placed on an upper outer side of an electrostatic chuck; a lower plasma focus ring tightly attached on the bottom of the upper plasma focus ring, and having a plurality of slots formed to induce flow of gas; and a coupling unit for detachably coupling the upper plasma focus ring and the lower plasma focus ring.

In addition, a method of manufacturing a plasma focus ring of a semiconductor etching apparatus according to the present invention comprises the steps of: cutting a plurality of raw materials to form an upper plasma focus ring and a lower plasma focus ring; processing a workpiece which forms the upper plasma focus ring by using a processing machine, and processing a workpiece which forms the lower plasma focus ring by using the processing machine; and detachably coupling the processed upper plasma focus ring and lower plasma focus ring to each other.

### CROSS-REFERENCE TO RELATED APPLICATIONS

This application claims the priority of the Korean Patent Applications NO 10-2019-0038097 filed on Apr. 1, 2019, in the Korean Intellectual Property Office, the disclosure of which is incorporated herein by reference.

### BACKGROUND OF THE INVENTION

### Field of the Invention

The present invention relates to a plasma focus ring of a semiconductor etching apparatus and a manufacturing method thereof, and more specifically, to a plasma focus ring of a semiconductor etching apparatus and a manufacturing method thereof, which can improve processability, extend lifespan, and reduce replacement cost by dividing the plasma focus ring into a plurality of workpieces, and manufacturing and combining the workpieces.

### Background of the Related Art

Generally, an etching technique used for manufacturing a semiconductor is a technique of processing a thin film quality formed on a semiconductor substrate in a desired pattern, and an etching apparatus is used for the processing.

Particularly, among the etching apparatuses, an etching apparatus that forms a pattern using plasma is called as a plasma etching apparatus or a dry etching apparatus, and the dry etching apparatus is mainly used for techniques that require a design rule of 0.15 μm or less.

FIG. 1 is a view showing a general dry etching apparatus, in which an electrostatic chuck 11 is provided inside a process chamber 10 to allow a wafer W to be seated, and a lower electrode 12 is provided on the bottom surface of the electrostatic chuck 11, and an upper electrode 13 is provided at a predetermined height from the electrostatic chuck 11.

Then, reaction gas is supplied from the top or one side of the process chamber 10 in which the upper electrode 13 is provided.

Therefore, if reaction gas is supplied therein and RF bias is applied to the lower electrode 12 and the upper electrode 13 while the wafer W is placed on the electrostatic chuck 11 of the process chamber 10, etching is achieved as plasma is generated on the top of the wafer W and collides with thin film quality of the wafer W.

During the process of etching the wafer W using plasma, the outside of the wafer W is usually surrounded by the edge ring 14 in the electrostatic chuck 11, and the plasma is uniformly distributed as far as the edge ring 14 of the wafer W.

In addition, as shown in FIG. 2, when the wafer is etched using an insulation film dry etching apparatus of Lam Research Co., USA, which currently has the most advanced technology in the insulation film (dielectric layer) etching among the semiconductor dry etching processes, a focus ring 15 made of silicon is used in an etching reaction chamber 10 to enhance the etching rate by increasing density of plasma, improve directionality of etching ions, and reduce foreign particles without sacrificing the selection rate.

As shown in FIGS. 2 to 4, a conventional focus ring 15 is manufactured as a single unit formed of polycrystal, and although there is a difference depending on the version, the focus ring 15 is generally formed in the shape of a donut on the whole, which has an outer diameter of about 520 mm, a height of about 48 mm, a cross section of C-shape, 250 slots 16 formed on the bottom cross-section, and exhaust holes (vent) 17 formed at two locations on the side surface.

As shown in FIG. 5, the conventional focus ring manufacturing method manufactures the focus ring 15 by processing a raw material of a disc shape (a) into a donut shape (b) by cutting the inner diameter to penetrate up and down, digging out the inner side (c) to make a donut shape having a cross-section of C shape, and turning over the workpiece and processing slots 16 (d) using advanced processing equipment 20 such as laser or electric discharge.

If the focus ring is manufactured in this manufacturing method, there is a problem in that a lot of machining processes are required to process in a C shape, and a dedicated tool is required due to the limited inner space, and it takes much processing time.

In addition, advanced equipment such as laser or electric discharge and advanced technologies are required to process the slots, and the slotted portions are floating in the air and difficult to be stably fixed since there is no separate fixing means. Therefore, there is a problem in that the processing yield is poor and loss of material is severe as the slot portions are easily broken in the case of brittle silicon.

In addition, since the conventional focus ring is worn out due to the etching on predetermined portions, the whole focus ring should be periodically replaced not to generate processing defects, and accordingly, there is a problem in that manufacturing cost increases due to the increased consumption of parts.

### SUMMARY OF THE INVENTION

Therefore, the present invention has been made in view of the above problems, and it is an object of the present invention to manufacture a plasma focus ring by dividing the plasma focus ring into upper and lower plasma focus rings and individually processing and combining the divided plasma focus rings to maximize processability and convenience of work, and cost can be reduced as only a part desired to be replaced can be replaced without replacing the whole plasma focus ring when the plasma focus ring is replaced.

In addition, the present invention may provide a plasma focus ring of a semiconductor etching apparatus and a manufacturing method thereof, which can minimize the defect rate of products through a stable work by processing slots while the plasma focus ring, in which the slots are processed, is stably placed on a workpiece fixing chuck without shaking.

To accomplish the above objects, according to one aspect of the present invention, there is provided a plasma focus ring of a semiconductor etching apparatus, the plasma focus ring comprising: an upper plasma focus ring placed on an upper outer side of an electrostatic chuck; a lower plasma focus ring tightly attached on the bottom of the upper plasma focus ring, and having a plurality of slots formed to induce flow of gas; and a coupling unit for detachably coupling the upper plasma focus ring and the lower plasma focus ring.

The coupling unit may include: a fastening groove formed in a bottom edge of the upper plasma focus ring; a coupling groove formed in an edge of the lower plasma focus ring to penetrate up and down; and a connection member inserted into the coupling groove and fastened to the fastening groove to couple the upper plasma focus ring and the lower plasma focus ring to each other.

The coupling unit may be provided in plurality at regular intervals to stably couple the upper plasma focus ring and the lower plasma focus ring.

The coupling unit may combine the contact points of the upper plasma focus ring and the lower plasma focus ring by bonding.

The coupling unit may combine the contact points of the upper plasma focus ring and the lower plasma focus ring by melting.

A method of manufacturing a plasma focus ring of a semiconductor etching apparatus may include the steps of: cutting a plurality of raw materials to form an upper plasma focus ring and a lower plasma focus ring; processing a workpiece which forms the upper plasma focus ring by using a processing machine, and processing a workpiece which forms the lower plasma focus ring by using the processing machine; and detachably coupling the processed upper plasma focus ring and lower plasma focus ring to each other.

In processing the upper plasma focus ring and the lower plasma focus ring, as the upper plasma focus ring is processed after being tightly attached on a workpiece fixing chuck when the upper plasma focus ring is processed, the upper plasma focus ring may be stably processed without vibration.

In processing the lower plasma focus ring and the lower plasma focus ring, as the lower plasma focus ring is processed after being tightly attached on a workpiece fixing chuck when the lower plasma focus ring is processed, the lower plasma focus ring may be stably processed without vibration.

At the step of detachably coupling the processed upper and lower plasma focus rings to each other, the upper and lower plasma focus rings are detachably coupled using a coupling unit.

### BRIEF DESCRIPTION OF THE DRAWINGS

FIG. 1 is a side cross-sectional view showing a general etching apparatus.

FIG. 2 is a side cross-sectional view showing an etching apparatus in which a focus ring is installed according to the prior art.

FIG. 3 is a perspective view showing a focus ring of an etching apparatus according to the prior art.

FIG. 4 is a cross-sectional view showing a focus ring of an etching apparatus according to the prior art.

FIG. 5 is a process diagram showing a method of manufacturing a focus ring of an etching apparatus according to the prior art.

FIG. 6 is an exploded perspective view showing a plasma focus ring of a semiconductor etching apparatus according to the present invention.

FIG. 7 is a combined perspective view showing a plasma focus ring of a semiconductor etching apparatus according to the present invention.

FIG. 8 is a before-coupling cross-sectional view showing a plasma focus ring of a semiconductor etching apparatus according to the present invention.

FIG. 9 is a combined cross-sectional view showing a plasma focus ring of a semiconductor etching apparatus according to the present invention.

FIG. 10 is a combined cross-sectional view showing another embodiment of a plasma focus ring of a semiconductor etching apparatus according to the present invention.

FIG. 11 is a process diagram showing a method of manufacturing a plasma focus ring of a semiconductor etching apparatus according to the present invention.

FIG. 12 is a flowchart illustrating a method of manufacturing a plasma focus ring of a semiconductor etching apparatus according to the present invention.

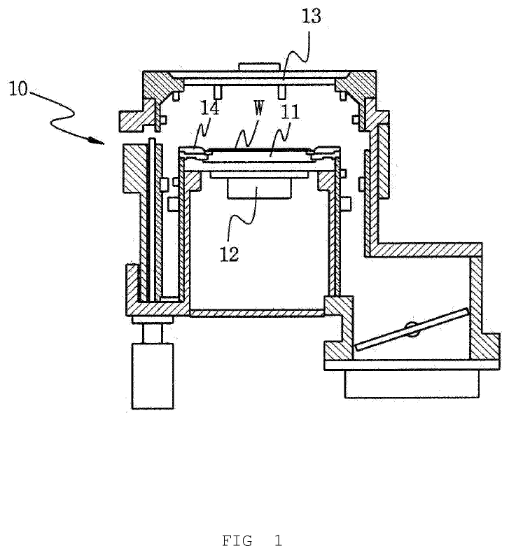

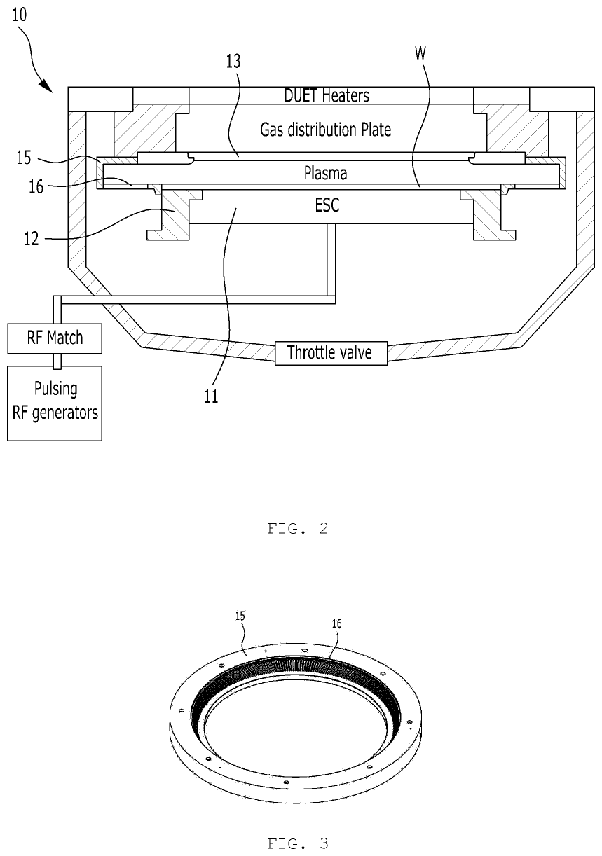

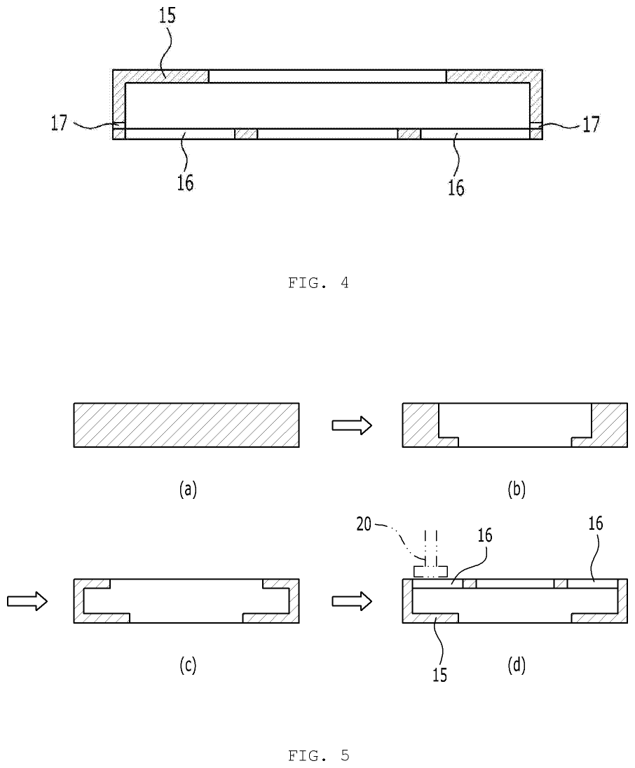

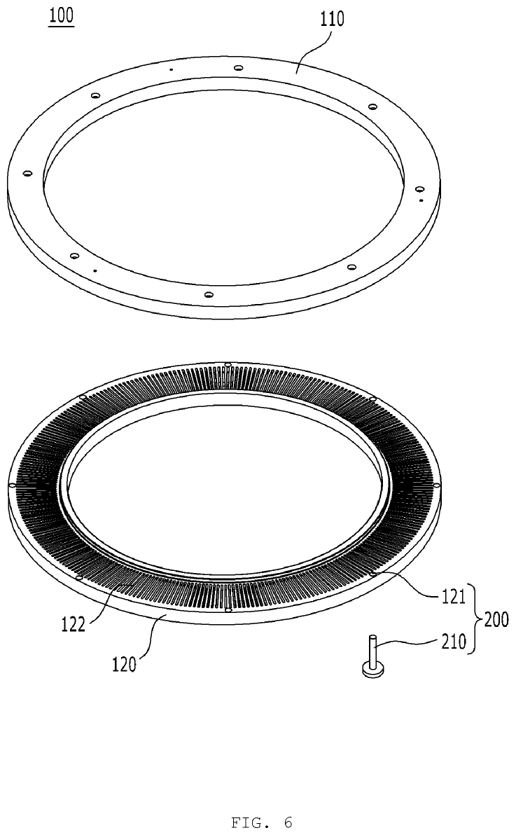

### DESCRIPTION OF SYMBOLS

100: Plasma focus ring
110: Upper plasma focus ring
111: Fastening groove
120: Lower plasma focus ring
121: Coupling groove
122: Slot
200: Coupling unit
210: Connection member
300: Processing machine
400: Workpiece fixing chuck

### DETAILED DESCRIPTION OF THE PREFERRED EMBODIMENT

Since the present invention may make diverse changes and have various embodiments, specific embodiments will be shown in the drawings and described in detail in the detailed description. However, this is not intended to limit the present invention to the specific embodiments, and it should be understood to include all modifications, equivalents and substitutes included in the spirit and scope of the present invention.

In the drawings, the embodiments of the present invention are not limited to the specific forms shown in the drawings and are exaggerated for clarity. Although specific terms are used in this specification, they are used for the purpose of describing the present invention, and are not used to restrict the meaning or to limit the scope of the present invention described in the claims.

In this specification, the term ‘and/or’ is used as a meaning including at least one of the components listed before and after the term. In addition, the term ‘connected/coupled’ is used as a meaning including that a component is directly connected to another component or indirectly connected through another component. In this specification, a singular form also includes a plural form unless otherwise specified in the phrase. Also, components, steps, operations and elements referred to as ‘comprising’ or ‘including’ used in the specification mean the presence or addition of one or more other components, steps, operations and elements.

In the description of the embodiments, the description that each layer (film), region, pattern or structure is formed “above/on” or “below/under” a substrate, each side (film), region, pad or pattern includes both those formed directly or via another layer. Standards of the “above/on” or “below/under” of each layer are described based on the drawings.

Hereinafter, an embodiment of the present invention will be described in detail with reference to the accompanying drawings.

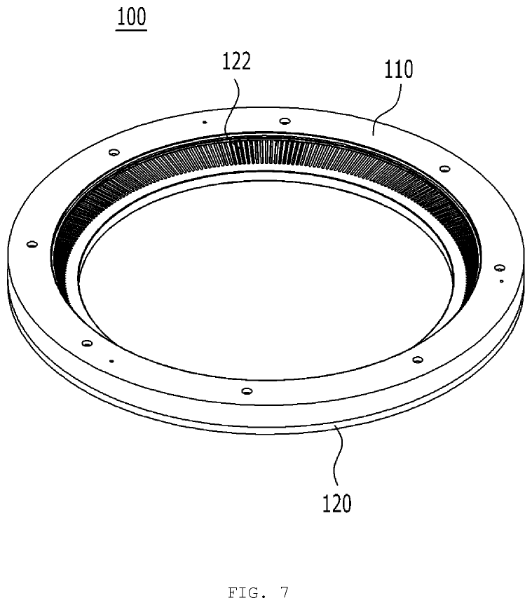

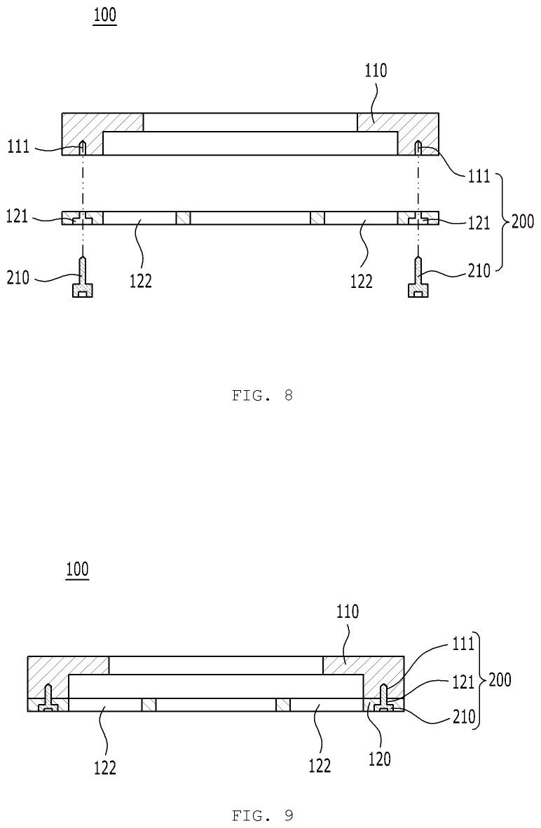

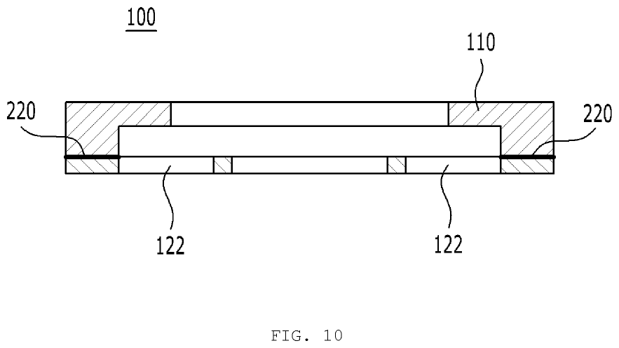

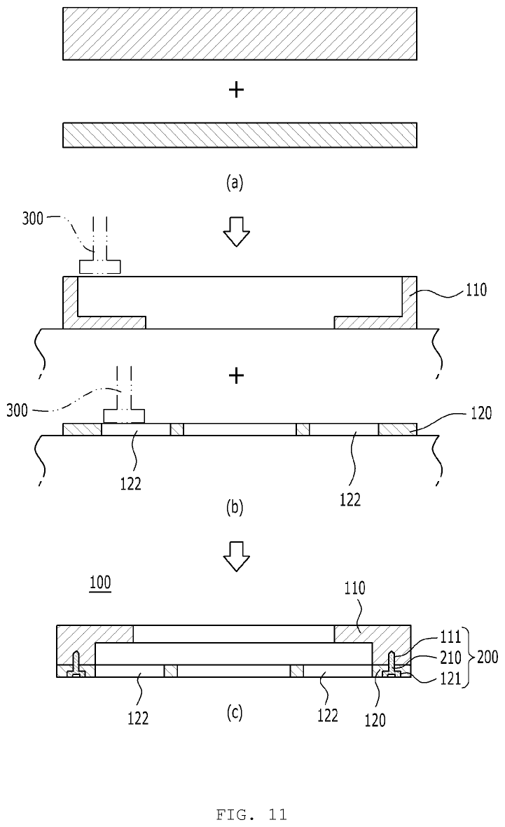

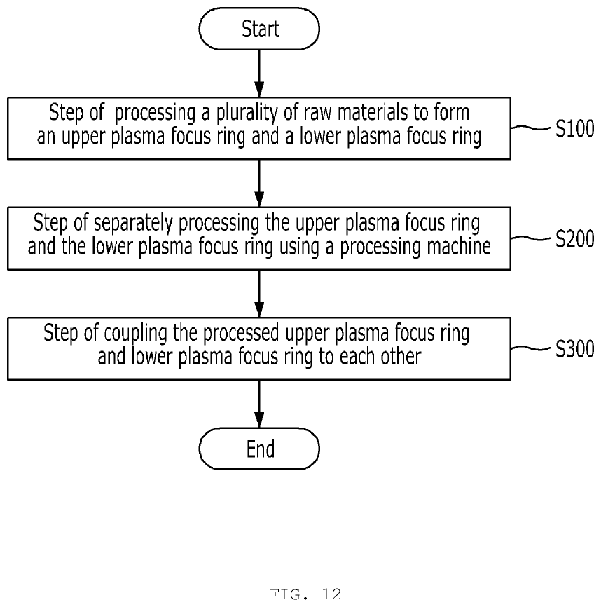

FIG. 6 is an exploded perspective view showing a plasma focus ring of a semiconductor etching apparatus according to the present invention, FIG. 7 is a combined perspective view showing a plasma focus ring of a semiconductor etching apparatus according to the present invention, FIG. 8 is a before-coupling cross-sectional view showing a plasma focus ring of a semiconductor etching apparatus according to the present invention, FIG. 9 is a combined cross-sectional view showing a plasma focus ring of a semiconductor etching apparatus according to the present invention, FIG. 10 is a combined cross-sectional view showing another embodiment of a plasma focus ring of a semiconductor etching apparatus according to the present invention, FIG. 11 is a process diagram showing a method of manufacturing a plasma focus ring of a semiconductor etching apparatus according to the present invention, and FIG. 12 is a flowchart illustrating a method of manufacturing a plasma focus ring of a semiconductor etching apparatus according to the present invention.

As shown in FIGS. 6 to 9 and 11, a plasma focus ring 100 of a semiconductor etching apparatus according to the present invention includes an upper plasma focus ring 110, a lower plasma focus ring 120, and a coupling unit 200.

The upper plasma focus ring 110 is placed on an upper outer side of an electrostatic chuck of a semiconductor etching apparatus.

In addition, the upper plasma focus ring 110 may be stably processed without shaking by using a processing machine 300 in a state that a workpiece of a disk shape is placed on and fixed to a workpiece fixing chuck 400.

The lower plasma focus ring 120 is processed separately from the upper plasma focus ring 110.

In addition, a plurality (250) of slots 122 is processed in the lower plasma focus ring 120 to induce flow of gas.

At this point, when the lower plasma focus ring 120 is processed, the lower plasma focus ring 120 may be stably processed without shaking by using a processing machine 300 in a state that the lower plasma focus ring 120 is placed on and fixed to the workpiece fixing chuck 400.

That is, as the lower plasma focus ring 120 is fixed to be tightly attached to the workpiece fixing chuck 400, the slots 122 of the lower plasma focus ring 120 are stably processed without vibration, and defects such as broken slots 122 or the like may be minimized.

In addition, the lower plasma focus ring 120 is tightly attached on the bottom of the upper plasma focus ring 110.

The coupling unit 200 detachably couples the upper plasma focus ring 110 and the lower plasma focus ring 120, which are processed separately from each other.

As shown in FIGS. 8 and 9, the coupling unit 200 includes a fastening groove 111, a coupling groove 121, and a connection member 210.

The fastening groove 111 is formed on the bottom of the upper plasma focus ring 110.

In addition, the fastening groove 111 is formed as a screw so that the connection member 210 may be bolted.

The coupling groove 121 is formed in the edge of the lower plasma focus ring 120 to penetrate up and down.

In addition, the fastening groove 111 and the coupling groove 121 are formed to communicate with each other.

The connection member 210 is made in the form of a bolt that is screwed to the fastening groove 111.

That is, as the connection member 210 is inserted into the coupling groove 121 and fastened to the fastening groove 111 while the fastening groove 111 and the coupling groove 121 communicate with each other, the upper plasma focus ring 110 and the lower plasma focus ring 120 may be easily coupled to or separated from each other.

In addition, a plurality of coupling units 200 spaced apart at regular intervals is provided in the upper and lower plasma focus rings 110 and 120 to increase the coupling force between the upper plasma focus ring 110 and the lower plasma focus ring 120.

In addition, when the upper and lower plasma focus rings 110 and 120 are coupled through the coupling unit 200, the coupling unit 200 couples the bottom surface of the upper plasma focus ring 110 and the top surface of the lower plasma focus ring 120 as tightly as possible.

As shown in FIG. 10, the coupling unit 200 couples the contact points of the upper plasma focus ring 110 and the lower plasma focus ring 120 with each other by bonding or melting 220.

As shown in FIGS. 11 and 12, a method of manufacturing a plasma focus ring of a semiconductor etching apparatus according to an embodiment of the present invention processes a raw material by cutting the raw material forming the plasma focus ring 100 into an upper plasma focus ring 110 and a lower plasma focus ring 120 (S100).

That is, the plasma focus ring 100 is cut into the upper plasma focus ring 110 and the lower plasma focus ring 120 to be separately processed.

Then, the workpieces separated into the upper plasma focus ring 110 and the lower plasma focus ring 120 are separately processed as the upper plasma focus ring 110 and the lower plasma focus ring 120 using a processing machine 300 (S200).

That is, as the plasma focus ring 100 is manufactured by dividing the plasma focus ring 100 into the upper plasma focus ring 110 and the lower plasma focus ring 120, the upper plasma focus ring 110 and lower plasma focus rings 120 are separately processed.

In addition, in processing the upper plasma focus ring 110 (S200), when the upper plasma focus ring 110 is processed, the upper plasma focus ring 110 is processed using the processing machine 300 while the upper plasma focus ring 110 is firmly placed on and fixed to the workpiece fixing chuck 400.

In addition, when the upper plasma focus ring 110 is processed, the fastening groove 111 is processed to connect the lower plasma focus ring 120 using the connection member 210.

Accordingly, as the upper plasma focus ring 110 is stably fixed to the workpiece fixing chuck 400, the upper plasma focus ring 110 is processed without vibration, and the defect rate may be lowered.

In addition, in processing the lower plasma focus ring 120 (S200), when the lower plasma focus ring 120 is processed, the lower plasma focus ring 120 is processed using the processing machine 300 while the lower plasma focus ring 120 is firmly placed on and fixed to the workpiece fixing chuck 400.

In addition, when the lower plasma focus ring 120 is processed, the coupling groove 121 is processed to penetrate up and down to communicate with the fastening groove 111 of the upper plasma focus ring 110.

That is, as the lower plasma focus ring 120 is stably fixed to the workpiece fixing chuck 400 without shaking, a plurality of slots 122 formed in the lower plasma focus ring 120 is processed without vibration, and the defect rate may be lowered.

In addition, when the upper plasma focus ring 110 and the lower plasma focus ring 120 are separately processed, the upper and lower plasma focus rings 110 and 120 are detachably coupled to each other while the upper plasma focus ring 110 and the lower plasma focus ring 120 are tightly attached to each other (S300).

In addition, when the upper plasma focus ring 110 and the lower plasma focus ring 120 are coupled to each other (S300), the upper plasma focus ring 110 and the upper plasma focus ring 110 are tightly attached to each other to communicate the fastening groove 111 and the coupling groove 121 with each other, and since the connection member 210 is fastened to the coupling groove 121 and the fastening groove 111, the upper plasma focus ring 110 and the lower plasma focus ring 120 may be detachably coupled using the coupling unit 200.

Describing the operating state according to the plasma focus ring of a semiconductor etching apparatus of the present invention made in the manufacturing method as described above, it is as follows.

As the plasma focus ring 100 is divided into the upper plasma focus ring 110 and the lower plasma focus ring 120 and separately processed, rather than being processed as a single workpiece, accessibility of the processing machine 300 is improved, and it is convenient to process, and the amount of labor and the processing time can be minimized.

In addition, since the upper plasma focus ring 110 and the lower plasma focus ring 120 are processed using the processing machine 300 in a state that they are tightly attached to the workpiece fixing chuck 400 as much as possible, stable and precise processing is possible as vibration is not generated. Particularly, since breakage or the like of the slots 122 can be prevented when the slots 122 are processed in the lower plasma focus ring 120, the defect rate of the plasma focus ring 100 can be minimized.

In addition, as the plasma focus ring 100 is divided into the upper plasma focus ring 110 and the lower plasma focus ring 120 and separately processed and then the upper plasma focus ring 110 and lower plasma focus rings 120 are detachably coupled using the coupling unit 200, when an abnormality occurs in any one of the upper and lower plasma focus rings, only a corresponding part may be replaced without replacing the whole plasma focus ring 100 by separating the upper plasma focus ring 110 and the lower plasma focus ring 120.

As described above, since the lifespans of the upper plasma focus ring 110 and the lower plasma focus ring 120 are different from each other, replacement cost can be reduced by varying replacement cycles, and thus the user's burden of cost can be reduced.

As described above, according to the plasma focus ring of a semiconductor etching apparatus according to the present invention and a manufacturing method thereof, since a plasma focus ring is divided into an upper plasma focus ring and a lower plasma focus ring, and the upper and lower plasma focus rings are separately processed while being placed on and fixed to a workpiece fixing chuck and combined with each other, the defect rate may be reduced and the processability can be maximized as the workpiece may be stably fixed during the process, and convenience and efficiency of work can be maximized as accessibility of the processing machine is improved.

In addition, since the plasma focus ring is divided into a plurality of workpieces and detachably coupled, the lifespans of the upper plasma focus ring and the lower plasma focus ring are different from each other, and thus the present invention has an effect of reducing cost by varying the replacement cycles.

As described above, the present invention is not limited to the specific preferred embodiments described above, and any person having ordinary knowledge in the technical field to which the present invention pertains may make diverse modified embodiments without departing from the gist of the present invention as claimed in the claims, and such changes are within the scope of the claims.

What is claimed is:

1. A plasma focus ring of a semiconductor etching apparatus, the plasma focus ring comprising:
an upper plasma focus ring placed on an upper outer side of an electrostatic chuck, having an “L” shaped cross-sectional structure formed with a step across an inner circumferential surface, and coupled to an upper electrode;
a lower plasma focus ring tightly attached to the upper plasma focus ring, and having a plurality of slots formed to induce flow of gas; and
a coupling unit for detachably coupling a top of the “L” shaped cross section of the upper plasma focus ring and one side of the lower plasma focus ring, wherein
plasma is formed in an inner space that is formed by coupling the upper plasma focus ring and the lower plasma focus ring.

2. The plasma focus ring according to claim 1, wherein the coupling unit is bonded through a fastening structure by a connection member, contact point bonding, or melting bonding, and is provided in plurality at regular intervals to stably couple the upper plasma focus ring and the lower plasma focus ring.

3. The plasma focus ring according to claim 2, wherein the fastening structure by a connection member includes:
a fastening groove formed in a bottom edge of the upper plasma focus ring;
a coupling groove formed in an edge of the lower plasma focus ring to penetrate up and down; and
the connection member inserted into the coupling groove and fastened to the fastening groove to couple the upper plasma focus ring and the lower plasma focus ring to each other.

4. A method of manufacturing a plasma focus ring of a semiconductor etching apparatus, the method comprising the steps of:
cutting a plurality of raw materials to form an upper plasma focus ring and a lower plasma focus ring;
processing a workpiece which forms the upper plasma focus ring by using a processing machine, and processing a workpiece which forms the lower plasma focus ring by using the processing machine; and
detachably coupling the processed upper plasma focus ring and lower plasma focus ring to each other, wherein
when the upper plasma focus ring is processed, the upper plasma focus ring is firmly placed on a workpiece fixing chuck and stably processed without vibration to have an “L” shaped cross-sectional structure formed with a step across an inner circumferential surface,
when the lower plasma focus ring is processed, the lower plasma focus ring is firmly placed on the workpiece fixing chuck and stably processed without vibration and has a plurality of slots formed to induce flow of gas,
the step of coupling the upper and lower plasma focus rings to each other is detachably coupling the upper plasma focus ring and the lower plasma focus ring using a plurality of coupling units spaced apart at regular intervals, and
an inner space in which plasma is formed is formed by coupling a top of the “L” shaped cross section of the upper plasma focus ring and one side of the lower plasma focus ring.

5. The method according to claim 4, wherein the coupling step is performed through fastening by a connection member, contact point bonding, or melting bonding.

6. The method according to claim 5, wherein the fastening by a connection member is coupling the upper plasma focus ring and the lower plasma focus ring to each other by inserting, after a fastening groove formed in a bottom edge of the upper plasma focus ring and a coupling groove of the lower plasma focus ring are positioned to be aligned with each other, the connection member into the coupling groove formed in an edge of the lower plasma focus ring to penetrate up and down, and fastening the inserted connection member to the fastening groove formed in the bottom edge of the upper plasma focus ring.
